(19) United States
(12) Patent Application Publication
(10) Pub. No.: US 2025/0083957 A1
(43) Pub. Date: Mar. 13, 2025

(54) NITRIDE, PIEZOELECTRIC BODY, PIEZOELECTRIC ELEMENT, FERROELECTRIC BODY, AND FERROELECTRIC ELEMENT

(71) Applicants: TDK Corporation, Chuo-ku, Tokyo (JP); NATIONAL INSTITUTE OF ADVANCED INDUSTRIAL SCIENCE AND TECHNOLOGY, Tokyo (JP)

(72) Inventors: Yukari INOUE, Chuo-ku, Tokyo (JP); Tomohiro TERADA, Chuo-ku, Tokyo (JP); Junichi KIMURA, Chuo-ku, Tokyo (JP); Masato UEHARA, Tosu-shi, Saga (JP); Kenji HIRATA, Tosu-shi, Saga (JP); Hiroshi YAMADA, Tosu-shi, Saga (JP); Morito AKIYAMA, Tosu-shi, Saga (JP)

(73) Assignees: TDK Corporation, Chuo-ku, Tokyo (JP); NATIONAL INSTITUTE OF ADVANCED INDUSTRIAL SCIENCE AND TECHNOLOGY, Tokyo (JP)

(21) Appl. No.: 18/727,123

(22) PCT Filed: Mar. 30, 2023
(86) PCT No.: PCT/JP2023/013246

§ 371 Date: Jul. 8, 2024

(30) Foreign Application Priority Data
Apr. 7, 2022 (JP) 2022-063815

(51) Int. Cl. C01B 21/06; H10N 30/076; H10N 30/853

(52) U.S. Cl. CPC C01B 21/0602; H10N 30/076; H10N 30/853; C01P 2002/50; C01P 2006/40

(57) ABSTRACT

A nitride contains zinc and a group 4 element. The group 4 element contained in the nitride is at least one kind of element selected from the group consisting of titanium and zirconium. A content of zinc in the nitride is expressed as [Zn] atomic %. A total content of the group 4 element in the nitride is expressed as [M] atomic %. In the nitride, [M]/([Zn]+[M]) is more than 20% and less than 50%.

### TECHNICAL FIELD

The present disclosure relates to a nitride, piezoelectric material, a piezoelectric element (piezoelectric device), a ferroelectric material, and a ferroelectric element (ferroelectric device).

### BACKGROUND ART

In recent years, micro electro mechanical systems (MEMS) have attracted attention. The MEMS (micro electro mechanical systems) are devices in which mechanical element components, electronic circuits, and the like are integrated on one substrate (for example, a semiconductor substrate) by using a microprocessing technology. In the MEMS, a piezoelectric effect or an inverse piezoelectric effect of a piezoelectric thin film is used. When manufacturing the MEMS using the piezoelectric thin film, a lower electrode layer, the piezoelectric thin film, and an upper electrode layer are stacked on a substrate such as silicon or sapphire. MEMS having any function can be obtained by the subsequent processes (microprocessing such as patterning, etching, and dicing). When selecting a piezoelectric thin film excellent in piezoelectric properties, a performance of the piezoelectric thin film element such as the MEMS is improved, and a reduction in size of the piezoelectric thin film element is realized. Piezoelectric properties of the piezoelectric thin film are evaluated on the basis of various piezoelectric constants (for example, a piezoelectric strain constant d₃₃) corresponding to the function of the piezoelectric thin film element.

As a piezoelectric composition constituting the piezoelectric thin film, for example, Pb(Zr, Ti)O₃ (lead zirconate titanate, abbreviation: PZT), LiNbO₃ (lithium niobate), AlN (aluminum nitride), ZnO (zinc oxide), and CdS (cadmium sulfide), and the like are known. In recent years, new piezoelectric compositions have been developed in order to obtain excellent piezoelectric properties. For example, as the new piezoelectric compositions, Non Patent Literature 1 described below discloses a nitride (TiZnN₂) consisting of titanium, zinc, and nitrogen, a nitride (ZrZnN₂) consisting of zirconium, zinc, and nitrogen, and a nitride (HfZnN₂) consisting of hafnium, zinc, and nitrogen. Non Patent Literature 2 described below discloses wurtzite type alloy expressed by TM_{x/2}M_{x/2}Al₁₋ₓN (TM=Ti, Zr, Hf; M=Mg, Ca, Zn).

### CITATION LIST

### Non Patent Literature

Non Patent Literature 1: C. Tholander et al, “Strong piezoelectric response in stable TiZnN₂, ZrZnN₂, and HfZnN₂ found by ab initio high-throughput approach”, JOURNAL OF APPLIED PHYSICS 120, 225102 (2016)
Non Patent Literature 2: C. Tholander et al, “Large piezoelectric response of quarternary wurtzite nitride alloys and its physical origin from first principles”, PHYSICAL REVIEW B 92, 174119 (2015)

### SUMMARY OF INVENTION

### Technical Problem

Phase diagrams and various physical property values (piezoelectric constant and the like) of the nitrides described in Non Patent Literatures 1 and 2 described above are merely results of simulation by the first-principles calculation. The simulation by the first-principles calculation is performed under various non-experimental conditions such as ideal atomic arrangement and an absolute zero temperature (zero K). In addition, the simulation by the first-principles calculation assumes a stoichiometric ratio that maintains a charge balance in the nitrides. Accordingly, a composition of a nitride suitable for practical use as a piezoelectric composition cannot be known from Non Patent Literatures 1 and 2. Furthermore, in the simulation described in Non Patent Literatures 1 and 2, dimensions and a shape of the piezoelectric composition are not considered. Accordingly, the composition of the nitride suitable for practical use as the piezoelectric thin film cannot be known from Non Patent Literatures 1 and 2.

In order to specify a composition of a nitride suitable for practical use, the present inventors actually prepared a piezoelectric thin film consisting of a nitride containing zinc and a group 4 element, and evaluated piezoelectric properties thereof. As a result, the present inventors obtained a finding that was not obtained from the simulation in Non Patent Literatures 1 and 2. In addition, the present inventors found that d₃₃ of the nitride increases by adding aluminum to the above nitride. A bond between Al and N is a covalent bond and is harder than an ionic bond such as a bond between Zn and N, and a bond between the group 4 element and N. The harder a chemical bond formed in the nitride is, the further piezoelectric properties of the nitride tend to deteriorate. Accordingly, aluminum is not usually added to a nitride containing zinc and the group 4 element.

An object of an aspect of the present invention is to provide a nitride excellent in piezoelectric properties, a piezoelectric material including the nitride, a piezoelectric element including the piezoelectric material, a ferroelectric material including a nitride, and a ferroelectric element including the ferroelectric material.

### Solution to Problem

A nitride according to a first aspect of the present invention is described as “a first nitride”. A nitride according to a second aspect of the present invention is described as “a second nitride”.

The first nitride contains zinc and a group 4 element. The group 4 element contained in the first nitride is at least one kind of element selected from the group consisting of titanium and zirconium. A content of zinc in the first nitride is expressed as [Zn] atomic %. A total content of the group 4 element in the first nitride is expressed as [M] atomic %. In the first nitride, [M]/([Zn]+[M]) is more than 20% and less than 50%.

The second nitride contains zinc and a group 4 element. The group 4 element contained in the second nitride is at least one kind of element selected from the group consisting of titanium and zirconium. The second nitride further contains aluminum. A content of zinc in the second nitride is expressed as [Zn] atomic %. A total content of the group 4 element in the second nitride is expressed as [M] atomic %. A content of aluminum in the second nitride is expressed as [Al] atomic %. In the second nitride, [M]/([Zn]+[M]) is more than 20% and less than 70%. In the second nitride, [Al]/([Zn]+[M]+[Al]) is 10% or more and less than 70%.

A piezoelectric material [1] according to an aspect of the present invention includes the first nitride or the second nitride.

A piezoelectric material [2] according to the aspect of the present invention includes a first piezoelectric layer including an aluminum nitride, and a second piezoelectric layer including the first nitride or the second nitride. The second piezoelectric layer is stacked directly on the first piezoelectric layer.

A piezoelectric element according to the aspect of the present invention includes the piezoelectric material [1] or the piezoelectric material [2].

A ferroelectric material [3] according to another aspect of the present invention includes the first nitride or the second nitride.

A ferroelectric material [4] according to another aspect of the present invention includes a first piezoelectric layer including an aluminum nitride, and a second piezoelectric layer including the first nitride or the second nitride. The second piezoelectric layer is stacked directly on the first piezoelectric layer.

A ferroelectric element according to another aspect of the present invention includes the ferroelectric material [3] or the ferroelectric material [4].

### Advantageous Effects of Invention

According to an aspect of the invention, a nitride excellent in piezoelectric properties, a piezoelectric material including the nitride, a piezoelectric element including the piezoelectric material, a ferroelectric material including a nitride, and a ferroelectric element including the ferroelectric material are provided.

### BRIEF DESCRIPTION OF DRAWINGS

FIG. 1 is a schematic cross-section of a piezoelectric thin film element (ferroelectric thin film element) according to an embodiment of the present invention, and a cross-section illustrated in FIG. 1 is orthogonal to a stacking direction of a substrate, an adhesive layer, a first electrode layer, a piezoelectric thin film, and a second electrode layer.

FIG. 2 is a schematic cross-section of a piezoelectric element (ferroelectric element) according to another embodiment of the invention, and a cross-section illustrated in FIG. 2 is orthogonal to a stacking direction of the first electrode layer, a piezoelectric layer, and the second electrode layer.

### DESCRIPTION OF EMBODIMENTS

Hereinafter, a preferred embodiment of the present invention will be described with reference to the accompanying drawings. In the drawings, the same reference numeral will be given to the same constituent element. The present invention is not limited to the following embodiment. X, Y, and Z in each of the drawings represent three coordinate axes orthogonal to each other.

A first nitride according to this embodiment contains zinc (Zn) and a group 4 element. The group 4 element contained in the first nitride is at least one kind of element selected from the group consisting of titanium (Ti) and zirconium (Zr). A content of zinc in a first nitride is expressed as [Zn] atomic %. A total content of the group 4 element in the first nitride is expressed as [M] atomic %. [M]/([Zn]+[M]) in the first nitride is more than 20% and less than 50%. That is, 100×[M]/([Zn]+[M]) in the first nitride is more than 20 and less than 50. It is not necessary for the first nitride to contain Al. That is, the first nitride may be a nitride that does not contain Al.

The first nitride may consist only of zinc, the group 4 element, and nitrogen (N). In a case where the first nitride consists only of zinc, the group 4 element, and nitrogen, the first nitride may be expressed by the following Chemical Formula 1.

Zn_{1-α}(Ti_{1-β}Zr_{β})_{α}N_{γ} (1)

α in Chemical Formula 1 is more than 0.20 and less than 0.50. β in Chemical Formula 1 is from 0.00 to 1.00. γ in Chemical Formula 1 is more than 0.00. γ in Chemical Formula 1 may equal to 2. As long as the first nitride has sufficient piezoelectric properties, γ in Chemical Formula 1 may be less than 2. As long as the first nitride has sufficient piezoelectric properties, γ in Chemical Formula 1 may be more than 2.

When the first nitride has the above-described composition, the first nitride can have excellent piezoelectric properties. In addition, when the first nitride has the above-described composition, the first nitride can have ferroelectric properties.

Theoretically, zinc in the first nitride is a divalent cation, a group 4 elements (Ti, Zr) in the first nitride are tetravalent cations, and N in the first nitride is a trivalent anion. According to theoretical estimation, in a case where [M]/([Zn]+[Ti]) in the first nitride is 50% (a stoichiometric ratio), the cations and the anion are likely to be electrically balanced. Accordingly, according to theoretical estimation, in a case where [M]/([Zn]+[Ti]) is 50% (a stoichiometric ratio), an electrical resistivity of the first nitride should be the highest, and the first nitride should be likely to have excellent piezoelectric properties. For example, a composition of a nitride in a stoichiometric ratio is expressed as Zn_{0.5}(Ti_{1-β}Zr_{β})_{0.5}N, or Zn(Ti_{1-β}Zr_{β})N₂. However, contrary to the theoretical estimation, due to a difference between the composition of the first nitride and the composition of the nitride in the stoichiometric ratio, the first nitride (particularly, a piezoelectric thin film consisting of the first nitride) is likely to have a high electrical resistivity, and the first nitride (particularly, the piezoelectric thin film consisting of the first nitride) can have excellent piezoelectric properties (for example, large d₃₃). In addition, due to the difference between the composition of the first nitride and the composition of the nitride in the stoichiometric ratio, the first nitride (particularly, the thin film consisting of the first nitride) can have ferroelectric properties (for example, a residual polarization value Pᵣ). That is, a piezoelectric thin film consisting of the first nitride may be a ferroelectric thin film.

In a case where, [M]/([Zn]+[M]) in the first nitride is 20% or less, charges derived from anions tend to be greater than charges derived from cations in the first nitride, and thus the electrical resistivity of the first nitride is extremely low, and the first nitride is less likely to have piezoelectric properties and ferroelectric properties. In a case where [M]/([Zn]+[M]) in the first nitride is 50% or more, since the cations and the anions are less likely to be electrically balanced, the electrical resistivity of the first nitride is extremely low, and the first nitride is less likely to have piezoelectric properties and ferroelectric properties.

Even though an attempt is made to produce a first nitride in which [M]/([Zn]+[M]) is 20% or less, a mixture containing an oxide of Zn and a nitride of Zn is likely to be formed. That is, it is difficult to form the first nitride in which [M]/([Zn]+[M]) is 20% or less. The mixture (thin film) containing the oxide of Zn and the nitride of Zn is likely to be peeled from an electrode (electrode layer), and thus it is difficult to measure piezoelectric properties and ferroelectric properties of the mixture containing the oxide of Zn and the nitride of Zn.

From the viewpoint that the first nitride is likely to have excellent piezoelectric properties and ferroelectric properties, [M]/([Zn]+[M]) in the first nitride may be from 24% to 49%, or from 32% to 44%. From the same reason, α in Chemical Formula 1 described above may be from 0.24 to 0.49, or from 0.32 to 0.44.

[Zn]/([Zn]+[M]) in the first nitride may be more than 50% and less than 80%, from 51% to 76%, or from 56% to 68%.

For example, d₃₃ of the first nitride (piezoelectric thin film consisting of the first nitride) may be from 0.5 pC/N to 6.0 pC/N, from 0.6 pC/N to 5.8 pC/N, or from 1.3 pC/N to 5.8 pC/N.

For example, the electrical resistivity ρ of the first nitride (piezoelectric thin film consisting of the first nitride) may be from 1.0×10⁹ Ω·cm to 1.0×10⁴ Ω·cm, or from 3.1×10⁹ Ω·cm to 1.0×10¹³ Ω·cm.

For example, the residual polarization value Pᵣ of the first nitride (ferroelectric thin film consisting of the first nitride) at 25° C. may be from 0.10 μC/cm² to 0.60 μC/cm², from 0.15 μC/cm² to 0.50 μC/cm², or from 0.23 μC/cm² to 0.50 μC/cm².

The second nitride contains zinc and a group 4 element. The group 4 element contained in the second nitride is at least one kind of element selected from the group consisting of titanium and zirconium. The second nitride further contains aluminum (Al). A content of zinc in the second nitride is expressed as [Zn] atomic %. A total content of the group 4 element in the second nitride is expressed as [M] atomic %. A content of aluminum in the second nitride is expressed as [Al] atomic %.

[M]/([Zn]+[M]) in the second nitride is more than 20% and less than 70%. That is, 100×[M]/([Zn]+[M]) in the second nitride is more than 20 and less than 70. [Al]/([Zn]+[M]+[Al]) in the second nitride is 10% or more and less than 70%. That is, 100×[Al]/([Zn]+[M]+[Al]) in the second nitride is 10 or more and less than 70.

[M]/([Zn]+[M]) in the second nitride may be more than 20% and less than 55%. That is, 100×[M]/([Zn]+[M]) in the second nitride may be more than 20 and less than 55. [Al]/([Zn]+[M]+[Al]) in the second nitride may be 10% or more and less than 50%. That is, 100×[Al]/([Zn]+[M]+[Al]) in the second nitride may be 10 or more and less than 50.

The second nitride may consist only of zinc, the group 4 element, aluminum, and nitrogen. In a case where the second nitride consists only of zinc, the group 4 element, aluminum, and nitrogen, the second nitride may be expressed by the following Chemical Formula 2.

{Zn_{1-α}(Ti_{1-β}Zr_{β})_{α}}_{1-δ}Al_{δ}N_{γ} (2)

α in Chemical Formula 2 is more than 0.20 and less than 0.70. α in Chemical Formula 2 may be more than 0.20 and less than 0.55. β in Chemical Formula 2 is from 0.00 to 1.00. δ in Chemical Formula 2 is 0.10 or more and less than 0.70. δ in Chemical Formula 2 may be 0.10 or more and less than 0.50. γ in Chemical Formula 2 is more than 0.00. γ in Chemical Formula 2 may be equal to 2. As long as the second nitride has sufficient piezoelectric properties, γ in Chemical Formula 2 may be less than 2. As long as the second nitride has sufficient piezoelectric properties, γ in Chemical Formula 2 may be more than 2.

50% may be excluded from the range of [M]/([Zn]+[M]) in the second nitride containing zinc, the group 4 element, and aluminum, and 50% and 65% may be excluded from the range of [Al]/([Zn]+[M]+[Al]) in the second nitride.

When the second nitride has the above-described composition, the second nitride (particularly, a piezoelectric thin film consisting of the second nitride) is likely to have a high electric resistivity, and the second nitride (particularly, the piezoelectric thin film consisting of the second nitride) can have excellent piezoelectric properties. In addition, when the second nitride has the above-described composition, the second nitride (particularly, the thin film consisting of the second nitride) can have ferroelectric properties (for example, a residual polarization value Pᵣ). That is, the piezoelectric thin film consisting of the second nitride may be a ferroelectric thin film. Since the second nitride contains aluminum in addition to zinc and the group 4 element, the second nitride is likely to have more excellent piezoelectric properties as compared with the first nitride that does not contain aluminum, and the second nitride is likely to have a more excellent ferroelectric properties as compared with the first nitride. For example, d₃₃ of the second nitride tends to be larger than d₃₃ of the first nitride, and Pᵣ of the second nitride tends to be larger than Pᵣ of the first nitride.

In a case where [M]/([Zn]+[M]) in the second nitride is 20% or less or 70% or more, the second nitride is less likely to have piezoelectric properties and ferroelectric properties. In a case where [Al]/([Zn]+[M]+[Al]) in the second nitride is less than 10%, the second nitride is less likely to have piezoelectric properties and ferroelectric properties. In a case where [Al]/([Zn]+[M]+[Al]) in the second nitride is 70% or more, the electrical resistivity of the second nitride is extremely low, and the second nitride is less likely to have piezoelectric properties and ferroelectric properties.

From the viewpoint that the second nitride is likely to have excellent piezoelectric properties and ferroelectric properties, [M]/([Zn]+[M]) in the second nitride may be from 21% to 69%, and [Al]/([Zn]+[M]+[Al]) in the second nitride may be from 10% to 69%. From the same reason, α in Chemical Formula 2 described above may be from 0.21 to 0.69, and δ in Chemical Formula 2 described above may be from 0.10 to 0.69.

From the viewpoint that the second nitride is likely to have excellent piezoelectric properties and ferroelectric properties, [M]/([Zn]+[M]) in the second nitride may be from 21% to 53%, and [Al]/([Zn]+[M]+[Al]) in the second nitride may be from 10% to 43%. From the same reason, α in Chemical Formula 2 described above may be from 0.21 to 0.53, and δ in Chemical Formula 2 described above may be from 0.10 to 0.43.

From the viewpoint that the second nitride is likely to have excellent piezoelectric properties and ferroelectric properties, [M]/([Zn]+[M]) in the second nitride may be from 34% to 47%, and [Al]/([Zn]+[M]+[Al]) in the second nitride may be from 16% to 41%. From the same reason, α in Chemical Formula 2 described above may be from 0.34 to 0.47, and δ in Chemical Formula 2 described above may be from 0.16 to 0.41.

[Zn]/([Zn]+[M]) in the second nitride may be 30% or more and less than 80%, more than 45% and less than 80%, from 47% to 79%, or from 53% to 76%.

For example, d₃₃ of the second nitride (piezoelectric thin film consisting of the second nitride) may be from 0.7 pC/N to 12.6 pC/N, from 0.8 pC/N to 12.5 pC/N, or from 4.5 pC/N to 12.5 pC/N.

For example, the electrical resistivity ρ of the second nitride (piezoelectric thin film consisting of the second nitride) may be from 1.0×10⁹ Ω·cm to 1.0×10¹⁴ Ω·cm.

For example, the residual polarization value Pᵣ of the second nitride (ferroelectric thin film consisting of the second nitride) at 25° C. may be from 0.09 μC/cm² to 2.30 μC/cm², from 0.10 μC/cm² to 2.25 μC/cm², from 0.20 μC/cm² to 2.25 μC/cm², or from 0.46 μC/cm² to 2.25 μC/cm².

The first nitride may further contain other elements in addition to zinc, titanium, zirconium, and nitrogen. The second nitride may further contain other elements in addition to zinc, titanium, zirconium, aluminum, and nitrogen.

A crystal structure of each of the first nitride and the second nitride is not limited. For example, a crystal of each of the first nitride and the second nitride may be hexagonal. For example, a crystal structure of each of the first nitride and the second nitride may be a wurtzite structure. In the crystal structure of the first nitride, Zn, Ti, and Zr may be substituted with each other. In the crystal structure of the second nitride, each of Zn, Ti, Zr, and Al may be substituted with each other. The crystal structure of the second nitride may be the same as the crystal structure of the first nitride except that the crystal structure of the second nitride contains Al. The crystal structure of the second nitride may be different from the crystal structure of the first nitride.

A piezoelectric material according to this embodiment includes the first nitride or the second nitride. For example, the piezoelectric material may be used in a piezoelectric element. For example, the piezoelectric material may be a piezoelectric thin film including the first nitride or the second nitride. However, the piezoelectric material may not be the piezoelectric thin film. For example, the piezoelectric material may be a coarse ceramic (sintered body) including the first nitride or the second nitride. In the following description, as an example of the piezoelectric element, a piezoelectric thin film element using the piezoelectric thin film is described. However, the piezoelectric element is not limited to the piezoelectric thin film element. A structure of the piezoelectric element is not limited to the following structure.

A ferroelectric material according to this embodiment includes the first nitride or the second nitride. For example, the ferroelectric material may be used in a ferroelectric element. For example, the ferroelectric material may be a ferroelectric thin film including the first nitride or the second nitride. However, the ferroelectric material may not be the ferroelectric thin film. For example, the ferroelectric material may be a coarse ceramic (sintered body) including the first nitride or the second nitride. For example, the ferroelectric element may be a ferroelectric thin film element using the ferroelectric thin film. However, the ferroelectric element is not limited to the ferroelectric thin film element. The following piezoelectric material is a ferroelectric material. The following piezoelectric thin film is a ferroelectric thin film. The following piezoelectric thin film element is a ferroelectric thin film element. The following piezoelectric element is a ferroelectric element. A structure of the ferroelectric element is not limited to the following structure.

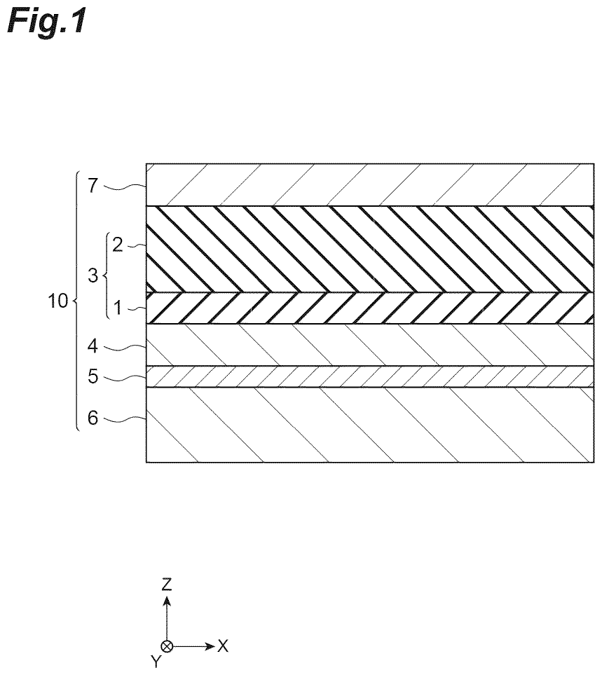

As illustrated in FIG. 1, a piezoelectric thin film element 10 (ferroelectric thin film element) according to this embodiment includes a substrate 6, an adhesive layer 5 stacked directly on a surface of the substrate 6, a first electrode layer 4 stacked indirectly on the surface of the substrate 6 through the adhesive layer 5, a piezoelectric thin film 3 (ferroelectric thin film) stacked directly on a surface of the first electrode layer 4, and a second electrode layer 7 stacked directly on a surface of the piezoelectric thin film 3.

The piezoelectric thin film 3 (ferroelectric thin film) may be composed of a plurality of layers. For example, the piezoelectric thin film 3 may include the first piezoelectric layer 1 including aluminum nitride (AlN), and the second piezoelectric layer 2 including the first nitride or the second nitride. The first piezoelectric layer 1 may consist only of aluminum nitride. The first piezoelectric layer 1 may consist of aluminum nitride including an additive element. The second piezoelectric layer 2 may consist only of the first nitride or the second nitride. The first piezoelectric layer 1 may be stacked directly on the surface of the first electrode layer 4, the second piezoelectric layer 2 may be stacked directly on the surface of the first piezoelectric layer 1, and the second electrode layer 7 may be stacked directly on the surface of the second piezoelectric layer 2. The first piezoelectric layer 1 may also be referred to as an intermediate layer disposed between the first electrode layer 4 and the second piezoelectric layer 2. Aluminum nitride contained in the first piezoelectric layer 1 is excellent in electrical insulation properties. Accordingly, when the first piezoelectric layer 1 is disposed between the first electrode layer 4 and the second piezoelectric layer 2, electrical insulation properties between the first electrode layer 4 and the second electrode layer 7 are improved as compared with a case where the first piezoelectric layer 1 is not present. A crystal lattice of aluminum nitride included in the first piezoelectric layer 1 is likely to match a crystal lattice of the second piezoelectric layer 2. Accordingly, when the second piezoelectric layer 2 is formed on the surface of the first piezoelectric layer 1, crystallinity and piezoelectric properties of the second piezoelectric layer 2 (the first nitride or the second nitride) are improved. The second piezoelectric layer 2 may be stacked directly on a part of the surface of the first piezoelectric layer 1, a part of the second electrode layer 7 may be stacked directly on the surface of the second piezoelectric layer 2, and the other part of the second electrode layer 7 may be stacked directly on the surface of the first piezoelectric layer 1. The second piezoelectric layer 2 may be stacked directly on the entirety of the surface of the first piezoelectric layer 1, and the second electrode layer 7 may be stacked directly on the entirety of the surface of the second piezoelectric layer 2.

The first piezoelectric layer 1 including aluminum nitride is not essential in the piezoelectric thin film element 10 (ferroelectric thin film element). The piezoelectric thin film 3 including only the first nitride or the second nitride as a nitride may be stacked directly on the surface of the first electrode layer 4. The piezoelectric thin film 3 may be stacked directly on a surface of the adhesive layer 5. The piezoelectric thin film 3 may be stacked directly on the surface of the substrate 6. The entirety of the piezoelectric thin film 3 may consist only of the first nitride or the second nitride.

The first nitride or the second nitride included in the piezoelectric thin film 3 (the second piezoelectric layer 2) may be a single crystal or a polycrystal. The first nitride or the second nitride in the piezoelectric thin film 3 (ferroelectric thin film) may be a columnar crystal extending in a normal direction (Z-axis direction) of the surface of the first electrode layer 4. For example, a (001) plane and a (002) plane of the first nitride or the second nitride in the piezoelectric thin film 3 (the second piezoelectric layer 2) may be parallel to the surface of the first electrode layer 4 (or the piezoelectric thin film 3). In other words, the (001) plane and the (002) plane of the first nitride or the second nitride in the piezoelectric thin film 3 (the second piezoelectric layer 2) may be oriented in a normal direction of the surface of the first electrode layer 4 (or the piezoelectric thin film 3). In a case where the piezoelectric thin film 3 (the second piezoelectric layer 2) includes a plurality of crystalline grains consisting of the first nitride or the second nitride, the (001) plane and the (002) plane of a part or the entirety of the crystalline grains may be parallel to the surface of the first electrode layer 4. In a case where the (001) plane and the (002) plane of the first nitride or the second nitride are parallel to the surface of the first electrode layer 4 (or the piezoelectric thin film 3), the piezoelectric thin film 3 (the second piezoelectric layer 2) is likely to have excellent piezoelectric properties and ferroelectric properties. However, the orientation direction of the lattice planes of the first nitride or the second nitride in the piezoelectric element is not limited.

Aluminum nitride included in the first piezoelectric layer 1 may be a single crystal or a polycrystal. Aluminum nitride in the first piezoelectric layer 1 may be a columnar crystal extending in a normal direction of the surface of the first electrode layer 4. A (001) plane and a (002) plane of aluminum nitride in the first piezoelectric layer 1 may be parallel to the surface of the first electrode layer 4 (or the piezoelectric thin film 3). In other words, the (001) plane and the (002) plane of aluminum nitride in the first piezoelectric layer 1 may be oriented in the normal direction of the surface of the first electrode layer 4 (or the piezoelectric thin film 3). In a case where the first piezoelectric layer 1 includes a plurality of crystalline grains consisting of aluminum nitride, the (001) plane and the (002) plane of a part or the entirety of the crystalline grains may be parallel to the surface of the first electrode layer 4.

In a case where the (001) plane and the (002) plane of aluminum nitride in the first piezoelectric layer 1 are parallel to the surface of the first electrode layer 4 (or the piezoelectric thin film 3), the (001) plane and the (002) plane of the first nitride or the second nitride in the second piezoelectric layer 2 are also likely to be parallel to the surface of the first electrode layer 4 (or the piezoelectric thin film 3). That is, the (001) plane and the (002) plane of aluminum nitride in the first piezoelectric layer 1 may be parallel to the (001) plane and the (002) plane of the first nitride or the second nitride in the second piezoelectric layer 2. A crystal orientation (polarization direction) in which piezoelectric properties of aluminum nitride are exhibited is [001] of the wurtzite structure. Accordingly, in a case where the (001) plane and the (002) plane of aluminum nitride are parallel to the surface of the first electrode layer 4 (or the piezoelectric thin film 3), the piezoelectric thin film 3 (the first piezoelectric layer 1) is likely to have excellent piezoelectric properties. However, the orientation direction of the lattice planes of aluminum nitride in the piezoelectric element is not limited.

For example, a thickness of the piezoelectric thin film 3 (ferroelectric thin film) may be from 50 nm to 30000 nm. In a case where the piezoelectric thin film 3 includes the first piezoelectric layer 1 and the second piezoelectric layer 2, a thickness of the first piezoelectric layer 1 may be from 5 nm to 50 nm, and a thickness of the second piezoelectric layer 2 may be from 45 nm to 29950 nm.

A stacking direction of the substrate 6, the adhesive layer 5, the first electrode layer 4, the piezoelectric thin film 3 (the first piezoelectric layer 1 and the second piezoelectric layer 2), and the second electrode layer 7 is the Z-axis direction. Each of the substrate 6, the adhesive layer 5, the first electrode layer 4, the piezoelectric thin film 3 (the first piezoelectric layer 1 and the second piezoelectric layer 2), and the second electrode layer 7 has a flat shape extending along an XY-plane direction (an X-axis and a Y-axis). A thickness of each of the substrate 6, the adhesive layer 5, the first electrode layer 4, the piezoelectric thin film 3 (the first piezoelectric layer 1 and the second piezoelectric layer 2), and the second electrode layer 7 may be uniform.

The adhesive layer 5 may directly cover a part or the entirety of the surface of the substrate 6. The first electrode layer 4 may directly cover a part or the entirety of the surface of the adhesive layer 5. The piezoelectric thin film 3 (the first piezoelectric layer 1) may directly or indirectly cover a part or the entirety of the surface of the first electrode layer 4. The piezoelectric thin film 3 (the first piezoelectric layer 1) may directly cover a part or the entirety of the surface of the adhesive layer 5. The piezoelectric thin film 3 (the first piezoelectric layer 1) may directly cover a part or the entirety of the surface of the substrate 6. The second electrode layer 7 may directly or indirectly cover a part or the entirety of the surface of the piezoelectric thin film 3 (the second piezoelectric layer 2). The second piezoelectric layer 2 may cover a part or the entirety of the surface of the first piezoelectric layer 1.

The adhesive layer 5 is not essential in the piezoelectric thin film element 10. In a case where the adhesive layer 5 is not present, the first electrode layer 4 may directly cover a part or the entirety of the surface of the substrate 6. The first electrode layer 4 may be referred to as a lower electrode layer. The second electrode layer 7 may be referred to as an upper electrode layer.

For example, the substrate 6 may be a semiconductor substrate such as a silicon substrate, a gallium arsenide substrate, or a silicon-on-insulator (SOI) substrate. The substrate 6 may be an optical crystal substrate (a sapphire substrate or the like), an insulating substrate (a glass substrate, a ceramic substrate, or the like), or a metal substrate (a stainless steel plate or the like).

The first electrode layer 4 may contain at least one element selected from the group consisting of platinum (Pt), iridium (Ir), gold (Au), rhodium (Rh), palladium (Pd), silver (Ag), nickel (Ni), copper (Cu), aluminum (Al), molybdenum (Mo), tungsten (W), vanadium (V), chromium (Cr), niobium (Nb), tantalum (Ta), ruthenium (Ru), zirconium (Zr), hafnium (Hf), titanium (Ti), yttrium (Y), scandium (Sc), and magnesium (Mg). The first electrode layer 4 may be a metal elementary substance. The first electrode layer 4 may be an alloy that contains at least two kinds of elements, a ceramic, or the like.

The adhesive layer 5 may contain at least one kind of element selected from the group consisting of aluminum (Al), silicon (Si), titanium (Ti), zinc (Zn), yttrium (Y), zirconium (Zr), cerium (Ce), chromium (Cr), niobium (Nb), molybdenum (Mo), hafnium (Hf), tantalum (Ta), tungsten (W), platinum (Pt), and ruthenium (Ru). The adhesive layer 5 may be a metal elementary substance, an alloy, or a compound (an oxide, a nitride, or the like). The adhesive layer 5 may be composed of another piezoelectric thin film, a polymer, or a ceramic. The adhesive layer 5 also has a function of suppressing peeling of the first electrode layer 4 due to mechanical impact or the like. The adhesive layer 5 may be referred to as an interfacial layer, a support layer, or a buffer layer.

The second electrode layer 7 may contain at least one kind of element selected from the group consisting of Pt, Ir, Au, Rh, Pd, Ag, Ni, Cu, Al, Mo, W, V, Cr, Nb, Ta, Ru, Zr, Hf, Ti, Y, Sc, and Mg. The second electrode layer 7 may be a metal elementary substance. The second electrode layer 7 may be an alloy that contains at least two kinds of elements selected from the above-described group, a ceramic, or the like.

For example, a thickness of the substrate 6 may be from 50 μm to 10000 μm. For example, a thickness of the adhesive layer 5 may be from 0.003 μm to 2 μm. For example, a thickness of the first electrode layer 4 may be from 0.01 μm to 1 μm. For example, a thickness of the second electrode layer 7 may be from 0.01 μm to 1 μm.

Each of the adhesive layer 5, the first electrode layer 4, the piezoelectric thin film 3 (the first piezoelectric layer 1 and the second piezoelectric layer 2), and the second electrode layer 7 may be stacked on the surface of the substrate 6 by a vapor deposition method such as sputtering.

For example, in a case where the first piezoelectric layer 1 consists only of aluminum nitride, the first piezoelectric layer 1 may be formed by sputtering using a metal target consisting of Al.

For example, in a case where the second piezoelectric layer 2 consists only of the first nitride, the second piezoelectric layer 2 may be formed by sputtering using at least one of a metal target consisting of Ti and a metal target consisting of Zr, and a metal target consisting of Zn.

For example, in a case where the second piezoelectric layer 2 consists only of the second nitride, the second piezoelectric layer 2 may be formed by sputtering using at least one of a metal target consisting of Ti and a metal target consisting of Zr, a metal target consisting of Zn, and a metal target consisting of Al.

For example, in a case where the entirety of the piezoelectric thin film 3 consists only of the first nitride, the piezoelectric thin film 3 may be formed by sputtering using at least one of a metal target consisting of Ti and a metal target consisting of Zr, and a metal target consisting of Zn.

For example, in a case where the entirety of the piezoelectric thin film 3 consists only of the second nitride, the piezoelectric thin film 3 may be formed by sputtering using at least one of a metal target consisting of Ti and a metal target consisting of Zr, a metal target consisting of Zn, and a metal target consisting of Al.

In sputtering using a plurality of metal targets, the higher an input power (power density) applied to each target is, the more an element derived from each target is likely to be contained in the piezoelectric thin film 3. Accordingly, a content of each element in the piezoelectric thin film 3 may be controlled by adjustment of the input power (power density) applied to each target. The input power (power density) may be referred to as power per unit area (unit: W/cm²) of each sputtering target.

An atmosphere (film formation atmosphere) of sputtering for forming the piezoelectric thin film 3 (the first piezoelectric layer 1 and the second piezoelectric layer 2) includes a nitrogen gas (N₂). Nitrogen contained in the piezoelectric thin film 3 is derived from the nitrogen gas in the film formation atmosphere. For example, the film formation atmosphere may be a mixed gas containing a rare gas (argon or the like) and a nitrogen gas. A content of nitrogen in the piezoelectric thin film 3 (the first piezoelectric layer 1 and the second piezoelectric layer 2) may be controlled by adjustment of a flow rate per unit time of the nitrogen gas supplied to the film formation atmosphere and an atmospheric pressure (a partial pressure of the nitrogen gas) of the film formation atmosphere. A duration of the sputtering, a temperature of a surface of the substrate during the sputtering, a substrate bias, and the like may be control factors of the composition and the thickness of the piezoelectric thin film 3 (the first piezoelectric layer 1 and the second piezoelectric layer 2). The piezoelectric thin film 3 having a desired shape or pattern may be formed by etching (for example, plasma etching).

Each of the adhesive layer 5, the first electrode layer 4, and the second electrode layer 7 may be formed by sputtering using at least one kind of target. Each of the adhesive layer 5, the first electrode layer 4, and the second electrode layer 7 may be formed by sputtering using a plurality of targets. A target that can be used to form each layer may contain at least one kind of element constituting each layer. It is possible to form each layer having a target composition by selection and combination of targets having a predetermined composition. For example, the target may be a metal elementary substance, an alloy, an oxide, or the like. Each layer may be formed in a rare gas (argon or the like). A part of elements constituting each layer may be derived from an atmosphere of the sputtering.

A crystal structure of each of the adhesive layer 5, the first electrode layer 4, the piezoelectric thin film 3 (the first piezoelectric layer 1 and the second piezoelectric layer 2), and the second electrode layer 7 may be specified by an X-ray diffraction (XRD) method. Compositions of each layer and the piezoelectric thin film 3 may be specified by at least any one analysis method among an X-ray fluorescence analysis (XRF), an X-ray photoelectron spectroscopy (XPS), an energy dispersive X-ray analysis (EDX), inductively coupled plasma mass spectrometry (ICP-MS), laser ablation inductively coupled plasma mass spectrometry (LA-ICP-MS), and electron beam microanalyzer (EPMA). A thickness of each of the adhesive layer 5, the first electrode layer 4, the piezoelectric thin film 3 (the first piezoelectric layer 1 and the second piezoelectric layer 2), and the second electrode layer 7 may be measured by a scanning electron microscope (SEM) on a cross-section, which is parallel to a thickness direction (the Z-axis direction in FIG. 1), of the piezoelectric thin film element 10.

Applications of the piezoelectric element or the ferroelectric element according to this embodiment are various. For example, the piezoelectric element or the ferroelectric element may be an actuator, a sensor, a microphone, a speaker, a harvester (vibration generator), an oscillator (timing device), a resonator (acoustic multilayer film), a high-frequency filter, a ferroelectric memory (FeRAM), or an X-ray generator (X-ray source). The piezoelectric element or the ferroelectric element may be a part or the entirety of MEMS. For example, the actuator may be a mirror actuator for a scanning image module. For example, the actuator may be used for haptics. That is, the actuator may be used in various devices for which a skin sensation (haptic) feedback is required. For example, the devices for which the skin sensation feedback is required may be a wearable device, a touch pad, a display, or a game controller. For example, the actuator may be used in a head assembly, a head stack assembly, or a hard disk drive. For example, the actuator may be used in a printer head, or an inkjet printer device. For example, the actuator may be used in a switch. For example, the sensor may be used as a pyroelectric sensor (for example, an infrared sensor), a vibration sensor, an acceleration sensor, a shock sensor, a gyro sensor, an acoustic emission (AE) sensor, a pressure sensor, a pulse wave sensor, an ultrasonic sensor, or an ultrasonic transducer such as a piezoelectric micromachined ultrasonic transducer (PMUT). For example, applications of the pyroelectric sensor may be a blood glucose sensor, a human detection sensor, a motion sensor, an infrared image sensor, an in-vehicle sensor, an infrared thermometer, a flame detection sensor, or a gas detection sensor. For example, a product applying the piezoelectric micromachined ultrasonic transducer may be a biometric authentication sensor, a medical or health care sensor (a fingerprint sensor or an ultrasonic blood vessel authentication sensor), or a time of flight (ToF) sensor. For example, the filter may be a bulk acoustic wave (BAW) filter, or a surface acoustic wave (SAW) filter.

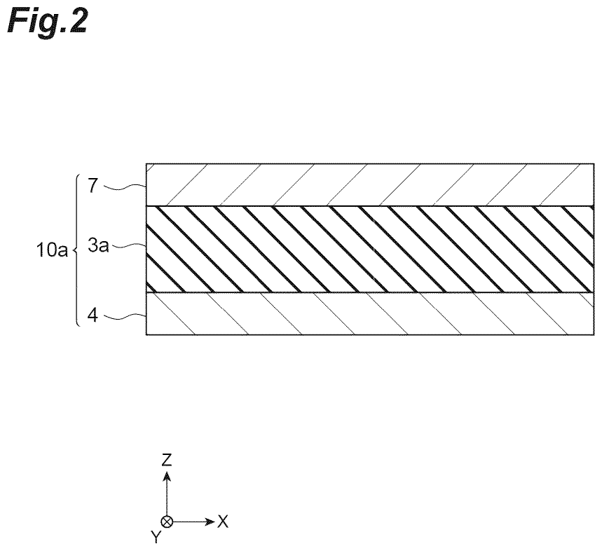

The present invention is not limited to the above-described embodiment. Various modifications of the present invention can be made within a range not departing from the gist of the present invention, and the modification examples are also included in the present invention. For example, as illustrated in FIG. 2, a piezoelectric element 10a (ferroelectric element) may include the first electrode layer 4, a piezoelectric layer 3a (ferroelectric layer) stacked directly on the first electrode layer 4, and the second electrode layer 7 stacked directly on the piezoelectric layer 3a (ferroelectric layer). The piezoelectric layer 3a (ferroelectric layer) includes the first nitride or the second nitride as a piezoelectric material (ferroelectric material). For example, the piezoelectric layer 3a (ferroelectric layer) may be a ceramic (sintered body) including the first nitride or the second nitride. For example, a thickness of the piezoelectric layer 3a (ferroelectric layer) may be from several mm to several tens of mm (for example, 10 mm).

### EXAMPLES

The present invention will be described in detail with reference to following Examples and Comparative Examples. The present invention is not limited by following Examples.

A nitride of each of following Examples 1 to 6 is an example of the first nitride.

### Example 1

### <Preparation of Nitride>

As a substrate, a wafer consisting of a single crystal of Si was used. A surface of the substrate was parallel to a (100) plane of Si. A thickness of the substrate was 725 μm. A diameter of the substrate was approximately 8 inches. The thickness of the substrate was uniform. A resistance of the substrate in a thickness direction was 100Ω or less.

A thin film (nitride film) including a nitride was formed directly on the entirety of the surface of the substrate by RF magnetron sputtering in a vacuum chamber. As a sputtering target, a metal target consisting of Zn (an elementary substance of Zn), and a metal target consisting of Ti (an elementary substance of Ti) was used. Input power (power density) of each sputtering target was adjusted so that [M]/([Zn]+[M]) in the nitride match a value shown in the following Table 1. An atmosphere in the vacuum chamber was a mixed gas of Ar and N₂. An atmospheric pressure in the vacuum chamber was 0.5 Pa. A flow rate per unit time of Ar supplied to the vacuum chamber was 15 sccm. A flow rate per unit time of N₂ supplied to the vacuum chamber was 15 sccm. A temperature of the substrate during forming the nitride film was maintained at 150° C. A thickness of the nitride film was adjusted to 0.5 μm.

### <Preparation of Thin Film Element>

As a sample different from the above-described sample (nitride film stacked directly on the surface of the substrate), a thin film element of Example 1 was prepared by the following method.

A first electrode layer (lower electrode layer) consisting of Mo was formed directly on the entirety of the surface of the above-described substrate by RF magnetron sputtering in the vacuum chamber. As a sputtering target, an elementary substance of Mo was used. An atmosphere in the vacuum chamber was an Ar gas. A thickness of the first electrode layer was uniform. The thickness of the first electrode layer was 0.2 μm.

A thin film (nitride film) consisting of a nitride was formed directly on the entirety of a surface of the first electrode layer by RF magnetron sputtering in the vacuum chamber. A method of forming the nitride film directly on the surface of the first electrode layer was the same as the method of forming the nitride directly on the surface of the substrate. A composition and dimensions of the nitride film formed directly on the surface of the first electrode layer were the same as the composition and dimensions of the above-described nitride film formed directly on the surface of the substrate.

A second electrode layer (electrode pattern) consisting of Ag was formed directly on the entirety of a surface of the nitride film by an electron beam deposition method using a metal mask in the vacuum chamber. A thickness of the second electrode layer was 0.1 μm. The thickness of the second electrode layer was uniform.

A stacked body prepared in the above-described procedure was composed of the substrate, the first electrode layer stacked directly on the substrate, the nitride film stacked directly on the first electrode layer, and the second electrode layer stacked directly on the nitride film. Patterning of the stacked structure on the substrate was performed by the subsequent photolithography. After the patterning, the entirety of the stacked body was cut by dicing to obtain a rectangular thin film element of Example 1. The thin film element was composed of the substrate, the first electrode layer stacked directly on the substrate, the nitride film stacked directly on the first electrode layer, and the second electrode layer stacked directly on the nitride film.

The thin film element of Example 1 was prepared by the above-described method. The following analysis and measurement were performed by using the above-described two kinds of samples.

### <Analysis of Composition of Nitride Film>

A composition of the nitride film formed directly on the surface of the substrate was analyzed by an X-ray fluorescence analysis (XRF) method, and [M]/([Zn]+[M]) in the nitride film was specified. A wavelength dispersive fluorescent X-ray device (RIGAKU AZX-400, manufactured by Rigaku Corporation) was used for the XRF method. The result of the analysis showed that the nitride (nitride film) of Example 1 consisted of Zn, Ti, and N. [M]/([Zn]+[M]) specified by the XRF method matched a value shown in the following Table 1. [Zn]/([Zn]+[M]) of Example 1 specified by the XRF method matched a value shown in the following Table 1.

### <Measurement of Crystal Structure of Nitride Film>

A crystal structure of the nitride film formed directly on the surface of the substrate was analyzed by an X-ray diffraction (XRD) method. A multi-purpose X-ray diffraction device (SmartLab, manufactured by Rigaku Corporation) was used for the XRD method. 2θ-θ scan, ω scan, and 2θχ-ϕ scan using the X-ray diffraction device were performed on the surface of the nitride film. As a result of the analysis based on the XRD method, it was confirmed that the nitride film has a wurtzite structure. A (002) plane of the wurtzite structure was parallel to the surface of each of the nitride film and the substrate.

### <Measurement of Electrical Resistivity ρ>

An electrical resistivity ρ of the nitride film between the first electrode layer and the second electrode layer was measured by applying a DC voltage between the first electrode layer and the second electrode layer in the thin film element of Example 1. The DC voltage was 1 V/μm. A duration time for applying the DC voltage was 30 seconds. The electrical resistivity ρ of the nitride film of Example 1 is shown in the following Table 1. “E+0n” (n is an arbitrary positive integer) in the following Table 1 represents “×10ⁿ”. “E+m” (m is an arbitrary positive integer) in the following Table 1 represents “×10^{m}”.

<Measurement of Piezoelectric Constant d₃₃>

A piezoelectric strain constant d₃₃ (unit: pC/N) of the nitride film of Example 1 was measured. Details of a method of measuring the piezoelectric strain constant d₃₃ were as follows. A result of the measurement showed that the nitride film of Example 1 was a thin film (piezoelectric thin film) having sufficient piezoelectric properties. The piezoelectric strain constant d₃₃ (an average value of three measurement points) of Example 1 is shown in the following Table 1. Measurement device: d₃₃ meter (PM200) manufactured by Piezotest Pte. Ltd.
Frequency: 110 Hz
Clamp pressure: 0.25 N

### <Measurement of Residual Polarization Value Pᵣ>

A hysteresis curve of the nitride film of Example 1 was measured. A residual polarization value (unit: μC/cm²) was read from the hysteresis curve. In the measurement of the hysteresis curve, a ferroelectric characteristic evaluation system (FCE) manufactured by TOYO Corporation was used. A frequency of an AC voltage in the measurement of the hysteresis curve was 10 kHz. A maximum value of a voltage applied to the nitride film in the measurement of the hysteresis curve was 20 Vpp. A temperature of the nitride film during measurement of the hysteresis curve was 25° C. The residual polarization value Pᵣ of Example 1 is shown in the following Table 1. The residual polarization value Pᵣ shown in the following Table 1 is an average value of three residual polarization values obtained by three times of measurement. The residual polarization value Pᵣ is an index indicating ferroelectric properties of the nitride film. The larger the residual polarization value Pᵣ is, the more the nitride film is excellent in ferroelectric properties.

### Examples 2 to 6, and Comparative Examples 1 to 5

As a sputtering target for forming a nitride film of each of Examples 2 to 4, and 6, and Comparative Examples 2 to 4, a metal target consisting of Zn (an elementary substance of Zn) and a metal target consisting of Ti (an elementary substance of Ti) were used as in Example 1.

As a sputtering target for forming a nitride film of Example 5, a metal target consisting of Zn (an elementary substance of Zn) and a metal target consisting of Zr (an elementary substance of Zr) were used.

When the nitride film of each of Examples 2 to 6, and Comparative Examples 2 to 4 was formed, an input power (power density) of each sputtering target was adjusted so that [M]/([Zn]+[M]) in the nitride match a value shown in the following Table 1.

As a sputtering target for forming the nitride film of Comparative Example 1, only a metal target consisting of Zn (an elementary substance of Zn) was used.

As a sputtering target for forming the nitride film of Comparative Example 5, only a metal target consisting of Ti (an elementary substance of Ti) was used.

In preparation of the thin film element of Example 6, an intermediate layer (first piezoelectric layer) was formed on the entirety of the surface of the first electrode layer, and a nitride film (second piezoelectric layer) was formed on the entirety of a surface of the intermediate layer. The intermediate layer of Example 6 was formed by the following method.

The intermediate layer consisting of AlN was formed by RF magnetron sputtering in the vacuum chamber. As a sputtering target, a metal target consisting of Al (an elementary substance of Al) was used. An atmosphere in the vacuum chamber was a mixed gas of Ar and N₂. A thickness of the intermediate layer was uniform. The thickness of the intermediate layer was adjusted to 0.03 μm.

Two kinds of samples of each of Examples 2 to 6, and Comparative Examples 1 to 5 were prepared by the same method as in Example 1 except for the above-described matters. Analysis and measurement using the two kinds of samples of each of Examples 2 to 6 and Comparative Examples 1 to 5 were performed by the same method as in Example 1.

Results of the analysis by the XRF method were as follows.

The nitride (nitride film) of each of Examples 2 to 4, and 6, and Comparative Examples 3 and 4 consisted of Zn, Ti, and N.

The nitride (nitride film) of Example 5 consisted of Zn, Zr, and N.

The nitride film of Comparative Example 1 was a mixture composed of a nitride of Zn and an oxide of Zn.

The nitride film of Comparative Example 2 was a mixture composed of a nitride containing Zn and Ti, and an oxide containing Zn and Ti.

The nitride film of Comparative Example 5 consisted of Ti and N.

[Mn]/([Zn]+[M]) of each of Examples 2 to 6 and Comparative Examples 1 to 5 matched a value shown in the following Table 1.

[Zn]/([Zn]+[M]) of each of Examples 2 to 6 and Comparative Examples 1 to 5 matched a value shown in the following Table 1.

Results of the analysis based on the XRD method were as follows.

The nitride film of each of Examples 2 to 6 had a wurtzite structure.

A (002) plane of the wurtzite structure of each of Examples 2 to 6 was parallel to a surface of each of the nitride film and the substrate.

An electrical resistivity p, a piezoelectric strain constant d₃₃, and a residual polarization value Pᵣ of each of Examples 2 to 6 and Comparative Examples 1 to 5 are shown in the following Table 1.

The result of the measurement of the piezoelectric strain constant d₃₃ showed that the nitride film of each of Examples 2 to 6 is a thin film (piezoelectric thin film) having sufficient piezoelectric properties.

The result of the measurement of residual polarization value Pᵣ showed that the nitride film of each of Examples 2 to 6 is a thin film (ferroelectric thin film) having ferroelectric properties.

In cases of Comparative Examples 1 and 2, since the nitride film including not only a nitride but also an oxide was formed, the electrical resistivity ρ of the nitride film was not measured. In the cases of Comparative Examples 1 and 2, since the nitride film constituting the thin film element was peeled from the first electrode layer, the piezoelectric strain constant d₃₃ and the residual polarization value Pᵣ could not be measured.

In cases of Comparative Examples 3 to 5, since the electrical resistivity ρ of the nitride film was too low, the piezoelectric strain constant d₃₃ and the residual polarization value Pᵣ could not be measured. Particularly, in a case of Comparative Example 5, since the electrical resistivity ρ of the nitride film was too low, the electrical resistivity ρ of the nitride film could not be accurately measured. That is, the nitride film of each of Comparative Examples 3 to 5 did not have insulating properties, piezoelectric properties, and ferroelectric properties.

TABLE 1

| | | | [M]/([Zn] + | [Zn]/([Zn] + | | Pᵣ | |
|---|---|---|---|---|---|---|---|
| | | Intermediate | [M]) | [M]) | d₃₃ | [μC/ | ρ |
| | M | layer | [atomic %] | [atomic %] | [pC/N] | cm²] | [Ω · cm] |
| Example 1 | Ti | — | 25 | 75 | 0.6 | 0.15 | 4.2E+10 |
| Example 2 | Ti | — | 32 | 68 | 1.3 | 0.23 | 1.2E+10 |
| Example 3 | Ti | — | 44 | 56 | 3.4 | 0.39 | 4.2E+10 |
| Example 4 | Ti | — | 49 | 51 | 0.8 | 0.17 | 8.5E+09 |
| Example 5 | Zr | — | 24 | 76 | 0.8 | 0.15 | 1.0E+13 |
| Example 6 | Ti | AlN | 41 | 59 | 5.8 | 0.50 | 3.1E+09 |
| Comparative | — | — | — | 100 | — | — | — |
| Example 1 | | | | | | | |
| Comparative | Ti | — | 19 | 81 | — | — | — |
| Example 2 | | | | | | | |
| Comparative | Ti | — | 50 | 50 | — | — | 3.4E+05 |
| Example 3 | | | | | | | |
| Comparative | Ti | — | 55 | 45 | — | — | 2.3E+04 |
| Example 4 | | | | | | | |
| Comparative | Ti | — | 100 | 0 | — | — | — |

### Examples 7 to 19, and Comparative Example 6

The following nitride of each of Examples 7 to 19 is an example of the second nitride.

As a sputtering target for forming a nitride film of each of Examples 7 to 19 and Comparative Example 6, a metal target consisting of Zn (an elementary substance of Zn), a metal target consisting of Ti (an elementary substance of Ti), and a metal target consisting of Al (an elementary substance of Al) were used.

When the nitride film of each of Examples 7 to 19 and Comparative Example 6 was formed, an input power (power density) of each sputtering target was adjusted so that [M]/([Zn]+[M]) and [Al]/([Zn]+[M]+[Al]) in the nitride match values shown in the following Table 2.

In cases of Examples 17 to 19, a flow rate per unit time of Ar supplied to the vacuum chamber during forming the nitride film was 10 sccm. In the cases of Examples 17 to 19, a flow rate per unit time of N₂ supplied to the vacuum chamber during forming the nitride film was 20 sccm.

In preparation of a thin film element of Example 16, an intermediate layer (first piezoelectric layer) was formed on the entirety of a surface of a first electrode layer, and a nitride film (second piezoelectric layer) was formed on the entirety of a surface of the intermediate layer. The intermediate layer of Example 16 was formed by the same method as in the intermediate layer of Example 6.

Two kinds of samples of each of Examples 7 to 19 and Comparative Example 6 were prepared by the same method as in Example 1 except for the above-described matters. Analysis and measurement using the two kinds of samples of each of Examples 7 to 19 and Comparative Example 6 were performed by the same method as in Example 1.

Results of the analysis by the XRF were as follows.

The nitride film of each of Examples 7 to 19, and Comparative Example 6 consisted of Zn, Ti, Al, and N.

[M]/([Zn]+[M]) of each of Examples 7 to 19 and Comparative Example 6 matched a value shown in the following Table 2.

[Al]/([Zn]+[M]+[Al]) of each of Examples 7 to 19 and Comparative Example 6 matched a value shown in the following Table 2.

Results of the analysis based on the XRD method were as follows.

The nitride film of each of Examples 7 to 19 had a wurtzite structure.

A (002) plane of the wurtzite structure of each of Examples 7 to 19 was parallel to a surface of each of the nitride film and the substrate.

A piezoelectric strain constant d₃₃, and a residual polarization value Pᵣ of each of Examples 7 to 19 are shown in the following Table 2.

The result of the measurement of the piezoelectric strain constant d₃₃ showed that the nitride film of each of Examples 7 to 19 is a thin film (piezoelectric thin film) having sufficient piezoelectric properties.

The result of the measurement of the residual polarization value Pᵣ showed that the nitride film of each of Examples 7 to 19 is a thin film (ferroelectric thin film) having ferroelectric properties.

The nitride film of Comparative Example 6 did not have insulating properties, piezoelectric properties, and ferroelectric properties.

TABLE 2

| | | Inter- | [M]/([Zn] + | [Al]/([Zn] + | | Pᵣ |
|---|---|---|---|---|---|---|
| | | mediate | [M]) | [M] + [Al]) | d₃₃ | [μC/ |
| | M | layer | [atomic %] | [atomic %] | [pC/N] | cm²] |
| Example 7 | Ti | — | 41 | 10 | 0.2 | 0.27 |
| Example 8 | Ti | — | 41 | 16 | 7.0 | 1.31 |
| Example 9 | Ti | — | 43 | 23 | 11.4 | 2.17 |
| Example 10 | Ti | — | 47 | 40 | 10.9 | 1.87 |
| Example 11 | Ti | — | 40 | 43 | 3.6 | 0.38 |
| Example 12 | Ti | — | 21 | 40 | 0.8 | 0.17 |
| Example 13 | Ti | — | 34 | 35 | 4.5 | 0.46 |
| Example 14 | Ti | — | 47 | 41 | 9.5 | 1.52 |
| Example 15 | Ti | — | 53 | 43 | 1.7 | 0.26 |
| Example 16 | Ti | AlN | 44 | 40 | 12.5 | 2.25 |
| Example 17 | Ti | — | 50 | 50 | 5.3 | 0.18 |
| Com- | Ti | — | 20 | 14 | — | — |
| parative | | | | | | |
| Example 6 | | | | | | |
| Example 18 | Ti | — | 55 | 47 | 6.5 | 0.19 |
| Example 19 | Ti | — | 69 | 69 | 2.0 | 0.10 |

### INDUSTRIAL APPLICABILITY

For example, the nitride according to an aspect of the present invention may be used in the above-described piezoelectric element.

### REFERENCE SIGNS LIST

1: first piezoelectric layer, 2: second piezoelectric layer, 3: piezoelectric thin film (ferroelectric thin film), 3a: piezoelectric layer (ferroelectric layer), 4: first electrode layer, 5: adhesive layer, 6: substrate, 7: second electrode layer, 10: piezoelectric thin film element (ferroelectric thin film element), 10a: piezoelectric element (ferroelectric element).

1: A nitride containing zinc and a group 4 element,
wherein the group 4 element is at least one kind of element selected from the group consisting of titanium and zirconium,
a content of zinc in the nitride is expressed as [Zn] atomic %,
a total content of the group 4 element in the nitride is expressed as [M] atomic %, and
[M]/([Zn]+[M]) is more than 20% and less than 50%.

2: A nitride containing zinc and a group 4 element,
wherein the group 4 element is at least one kind of element selected from the group consisting of titanium and zirconium,
the nitride further contains aluminum,
a content of zinc in the nitride is expressed as [Zn] atomic %,
a total content of the group 4 element in the nitride is expressed as [M] atomic %,
a content of aluminum in the nitride is expressed as [Al] atomic %,
[M]/([Zn]+[M]) is more than 20% and less than 70%, and
[Al]/([Zn]+[M]+[Al]) is 10% or more and less than 70%.

3: A piezoelectric material comprising the nitride according to claim 1.

4: The piezoelectric material according to claim 3, comprising:
a first piezoelectric layer including an aluminum nitride; and
a second piezoelectric layer including the nitride,
wherein the second piezoelectric layer is stacked directly on the first piezoelectric layer.

5: A piezoelectric element comprising the piezoelectric material according to claim 3.

6: A piezoelectric element comprising the piezoelectric material according to claim 4.

7: A ferroelectric material comprising the nitride according to claim 1.

8: The ferroelectric material according to claim 7, comprising:
a first piezoelectric layer including an aluminum nitride; and
a second piezoelectric layer including the nitride,
wherein the second piezoelectric layer is stacked directly on the first piezoelectric layer.

9: A ferroelectric element comprising the ferroelectric material according to claim 7.

10: A ferroelectric element comprising the ferroelectric material according to claim 8.

11: A piezoelectric material comprising the nitride according to claim 2.

12: The piezoelectric material according to claim 11, comprising:
a first piezoelectric layer including an aluminum nitride; and
a second piezoelectric layer including the nitride,
wherein the second piezoelectric layer is stacked directly on the first piezoelectric layer.

13: A piezoelectric element comprising the piezoelectric material according to claim 11.

14: A piezoelectric element comprising the piezoelectric material according to claim 12.

15: A ferroelectric material comprising the nitride according to claim 2.

16: The ferroelectric material according to claim 15, comprising:
a first piezoelectric layer including an aluminum nitride; and
a second piezoelectric layer including the nitride,
wherein the second piezoelectric layer is stacked directly on the first piezoelectric layer.

17: A ferroelectric element comprising the ferroelectric material according to claim 15.

18: A ferroelectric element comprising the ferroelectric material according to claim 16.
